(19) United States
(12) Patent Application Publication
(10) Pub. No.: US 2025/0323658 A1
(43) Pub. Date: Oct. 16, 2025

(54) PIPELINE ANALOG-TO-DIGITAL CONVERTER

(71) Applicant: Chongqing GigaChip Technology Co., Ltd., Chongqing (CN)

(72) Inventors: Yabo NI, Chongqing (CN); Yong ZHANG, Chongqing (CN); Jiahao PENG, Chongqing (CN); Ting LI, Chongqing (CN); Can ZHU, Chongqing (CN); Liang LI, Chongqing (CN); Dongbing FU, Chongqing (CN); Jianan WANG, Chongqing (CN)

(73) Assignee: Chongqing GigaChip Technology Co., Ltd., Chongqing (CN)

(21) Appl. No.: 19/250,022

(22) Filed: Jun. 25, 2025

Related U.S. Application Data
(63) Continuation of application No. PCT/CN2023/074198, filed on Feb. 2, 2023.

(30) Foreign Application Priority Data
Dec. 31, 2022 (CN) 202211738580.5

(51) Int. Cl. H03M 1/46

(52) U.S. Cl. CPC H03M 1/46

(57) ABSTRACT

A pipeline analog-to-digital converter includes N pipeline conversion stages cascaded in sequence, and in the first N−1 pipeline conversion stages, at least one pipeline conversion stage includes a dither generating module and a multiplying digital-to-analog conversion module. In the present application, a flash-type analog-to-digital conversion unit in the multiplying digital-to-analog conversion module includes a quantization reference level generating circuit, and under the action of a random digital signal, the quantization reference level of a comparator in the flash-type analog-to-digital conversion unit is shifted by the quantization reference level generating circuit, thereby equivalently adding a dither signal to an input analog signal.

### CROSS REFERENCE TO RELATED APPLICATION

The present disclosure is a continuation application of International Patent Application No. PCT/CN2023/074198, filed on Feb. 2, 2023, which claiming the priority to Chinese Application No. 202211738580.5 filed on Dec. 31, 2022, the contents of all of which are incorporated herein by reference in their entirety for all purposes.

### TECHNICAL FIELD

The present application relates to the technical field of analog-digital hybrid integrated circuits, and in particular to a pipeline analog-to-digital converter.

### BACKGROUND

With the continuous improvement of the performance of analog-to-digital converters (ADCs), dither technology has been widely used in analog-to-digital converters. For pipeline ADCs, the linearity is generally improved by injecting dithers of known weights at the input stage. The conventional pipeline ADC with input dithers includes a dither generator, a sample-and-hold circuit (SH), and a multi-stage cascaded multiplying digital-to-analog converter (MDAC).

### SUMMARY

A pipeline analog-to-digital converter includes N pipeline conversion stages cascaded in sequence, wherein at least one of the first N−1 pipeline conversion stages includes: a dither generating module, generating a random digital signal and performing digital-to-analog conversion on the random digital signal to obtain a random analog signal; and a multiplying digital-to-analog conversion module, including a flash-type analog-to-digital conversion unit, a digital-to-analog conversion unit, and an operation unit, wherein the flash-type analog-to-digital conversion unit receives a first analog signal and performs analog-to-digital conversion on the first analog signal to obtain a digital signal, the digital-to-analog conversion unit receives the digital signal and performs digital-to-analog conversion on the digital signal to obtain a second analog signal, the operation unit receives the first analog signal, the second analog signal, and the random analog signal, and the operation unit obtains a residual analog signal equal to the first analog signal plus the random analog signal minus the second analog signal, wherein the flash-type analog-to-digital conversion unit also receives the random digital signal, and shifts a quantization reference level of a comparator in the flash-type analog-to-digital conversion unit under an action of the random digital signal, to equivalently add a dither signal to the first analog signal; N is an integer greater than 2.

In one or more embodiments, the flash-type analog-to-digital conversion unit includes a quantization reference level generating circuit, the quantization reference level generating circuit generates a plurality of quantization reference levels of different values, and the quantization reference level generating circuit is connected to the random digital signal to shift each of the quantization reference levels under the action of the random digital signal.

In one or more embodiments, the quantization reference level generating circuit includes: a current and voltage generating subcircuit, generating a first voltage and a second voltage, and generating a reference current; a voltage dividing subcircuit, connected to the first voltage and the second voltage, combining the first voltage and the second voltage to perform voltage dividing processing to obtain a plurality of quantization reference levels of different values; and a current mirror selecting subcircuit, connected to the current and voltage generating subcircuit and the voltage dividing subcircuit to mirroring the reference current to obtain a mirror current, and also connected to the random digital signal to selectively input the mirror current into the voltage dividing subcircuit under the control of the random digital signal, to shift each of the quantization reference levels by a voltage difference respectively generated by the mirror current.

In one or more embodiments, the current and voltage generating subcircuit includes a first operational amplifier, a second operational amplifier, a first PMOS transistor, a first NMOS transistor, a first resistor, a second resistor, a third resistor, a fourth resistor, a fifth resistor, and a sixth resistor, a source of the first PMOS transistor is connected to a power supply voltage, a drain of the first PMOS transistor is connected to a drain of the first NMOS transistor via the first resistor and the second resistor connected in series in sequence, a source of the first NMOS transistor is grounded, an inverting input end of the first operational amplifier is grounded via the third resistor connected in series, the inverting input end of the first operational amplifier is also connected to the drain of the first PMOS transistor via the fourth resistor connected in series, a non-inverting input end of the first operational amplifier is connected to a first reference voltage via the fifth resistor connected in series, the non-inverting input end of the first operational amplifier is also connected to the drain of the first NMOS transistor via the sixth resistor connected in series, an output end of the first operational amplifier is connected to a gate of the first PMOS transistor, an inverting input end of the second operational amplifier is connected to a common end of the first resistor and the second resistor, a non-inverting input end of the second operational amplifier is connected to a second reference voltage, and an output end of the second operational amplifier is connected to a gate of the first NMOS transistor; wherein the drain of the first PMOS transistor outputs the first voltage, the drain of the first NMOS transistor outputs the second voltage, the drain of the first PMOS transistor outputs the reference current, and the drain of the first NMOS transistor inputs the reference current.

In one or more embodiments, a resistance value of the first resistor is equal to a resistance value of the second resistor, a resistance values of the third resistor, the fourth resistor, the fifth resistor, and the sixth resistor are equal, and the resistance value of the first resistor is greater than the resistance value of the third resistor.

In one or more embodiments, the voltage dividing subcircuit includes a seventh resistor, an eighth resistor, a ninth resistor, a tenth resistor, an eleventh resistor, a twelfth resistor, a thirteenth resistor, a fourteenth resistor, a fifteenth resistor, a sixteenth resistor, a seventeenth resistor, an eighteenth resistor, a nineteenth resistor, a twentieth resistor, a twenty-first resistor, a twenty-second resistor, a twenty-third resistor, and a twenty-fourth resistor, one end of the seventh resistor is connected to the drain of the first PMOS transistor, the other end of the seventh resistor is connected to the drain of the first NMOS transistor via the eighth resistor, the ninth resistor, the tenth resistor, the eleventh resistor, the twelfth resistor, the thirteenth resistor, the fourteenth resistor, and the fifteenth resistor connected in series in sequence, one end of the sixteenth resistor is connected to the drain of the first PMOS transistor, the other end of the sixteenth resistor is connected to the drain of the first PMOS transistor via the seventeenth resistor, the eighteenth resistor, the nineteenth resistor, the twentieth resistor, the twenty-first resistor, the twenty-second resistor, the twenty-third resistor, and the twenty-fourth resistor connected in series in sequence; wherein, a common end of the sixteenth resistor and the seventeenth resistor outputs one of the quantization reference levels, a common end of the seventeenth resistor and the eighteenth resistor outputs one of the quantization reference levels, a common end of the eighteenth resistor and the nineteenth resistor outputs one of the quantization reference levels, a common end of the nineteenth resistor and the twentieth resistor outputs one of the quantization reference levels, a common end of the twentieth resistor and the twenty-first resistor outputs one of the quantization reference levels, a common end of the twenty-first resistor and the twenty-second resistor outputs one of the quantization reference levels, a common end of the twenty-second resistor and the twenty-third resistor outputs one of the quantization reference levels, and a common end of the twenty-third resistor and the twenty-fourth resistor outputs one of the quantization reference levels.

In one or more embodiments, the resistance values of the seventh resistor, the fifteenth resistor, the sixteenth resistor, and the twenty-fourth resistor are equal, the resistance values of the eighth resistor, the ninth resistor, the tenth resistor, the eleventh resistor, the twelfth resistor, the thirteenth resistor, the fourteenth resistor, the seventeenth resistor, the eighteenth resistor, the nineteenth resistor, the twenty-tenth resistor, the twenty-first resistor, the twenty-second resistor, and the twenty-third resistor are equal; and a ratio of the resistance value of the eighth resistor to the resistance value of the seventh resistor is 2:1.

In one or more embodiments, the random digital signal includes a first random digital signal and a second random digital signal, the current mirror selecting subcircuit includes a second PMOS transistor, a third PMOS transistor, a fourth PMOS transistor, a fifth PMOS transistor, a second NMOS transistor, a third NMOS transistor, a fourth NMOS transistor, and a fifth NMOS transistor, a source of the second PMOS transistor is connected to the power supply voltage, a gate of the second PMOS transistor is connected to the gate of the first PMOS transistor, a drain of the second PMOS transistor is connected to a source of the fourth PMOS transistor, a gate of the fourth PMOS transistor is connected to the first random digital signal, a drain of the fourth PMOS transistor is connected to a common end of the seventh resistor and the eighth resistor, a source of the third PMOS transistor is connected to the power supply voltage, a gate of the third PMOS transistor is connected to the gate of the first PMOS transistor, a drain of the third PMOS transistor is connected to a source of the fifth PMOS transistor, a gate of the fifth PMOS transistor is connected to the second random digital signal, a drain of the fifth PMOS transistor is connected to the common end of the sixteenth resistor and the seventeenth resistor, a drain of the second NMOS transistor is connected to a common end of the fourteenth resistor and the fifteenth resistor, a gate of the second NMOS transistor is connected to the first random digital signal, a source of the second NMOS transistor is connected to a drain of the fourth NMOS transistor, a gate of the fourth NMOS transistor is connected to the gate of the first NMOS transistor, a source of the fourth NMOS transistor is grounded, a drain of the third NMOS transistor is connected to the common end of the twenty-third resistor and the twenty-fourth resistor, a gate of the third NMOS transistor is connected to the second random digital signal, a source of the third NMOS transistor is connected to a drain of the fifth NMOS transistor, a gate of the fifth NMOS transistor is connected to the gate of the first NMOS transistor, and a source of the fifth NMOS transistor is grounded.

In one or more embodiments, a ratio of a width-to-length ratio of the second PMOS transistor to a width-to-length ratio of the first PMOS transistor is M:2, and a ratio of a width-to-length ratio of the third PMOS transistor to a width-to-length ratio of the first PMOS transistor is M:2; a ratio of a width-to-length ratio of the second NMOS transistor to a width-to-length ratio of the first NMOS transistor is M:2, and a ratio of a width-to-length ratio of the third NMOS transistor to a width-to-length ratio of the first NMOS transistor is M:2.

In one or more embodiments, the first random digital signal and the second random digital signal are mutually inverted signals; when a value of the first random digital signal is 1, a value of the second random digital signal is −1; when a value of the first random digital signal is −1, a value of the second random digital signal is 1.

### BRIEF DESCRIPTION OF DRAWINGS

FIG. 1 shows a circuit structure diagram of a pipeline conversion stage in a pipeline analog-to-digital converter with input dithers.

FIG. 2 is a circuit diagram showing a pipeline conversion stage in a pipeline analog-to-digital converter according to the present application.

FIG. 3 to FIG. 5 show working principles of a flash-type analog-to-digital conversion unit with pre-quantization function in the present application.

FIG. 6 to FIG. 7 show working principles of a quantization reference level generating circuit in the present application.

FIG. 8 is a circuit diagram showing a quantization reference level generating circuit in an optional embodiment of the present application.

### DESCRIPTION OF EMBODIMENTS

The following describes the embodiments of the present application through specific examples, and those skilled in the art may easily understand other advantages and effects of the present application from the contents disclosed in this specification. The present application may also be implemented or applied through other specific embodiments, and the details in this specification may also be modified or changed in various ways based on different viewpoints and applications without departing from the spirit of the present application.

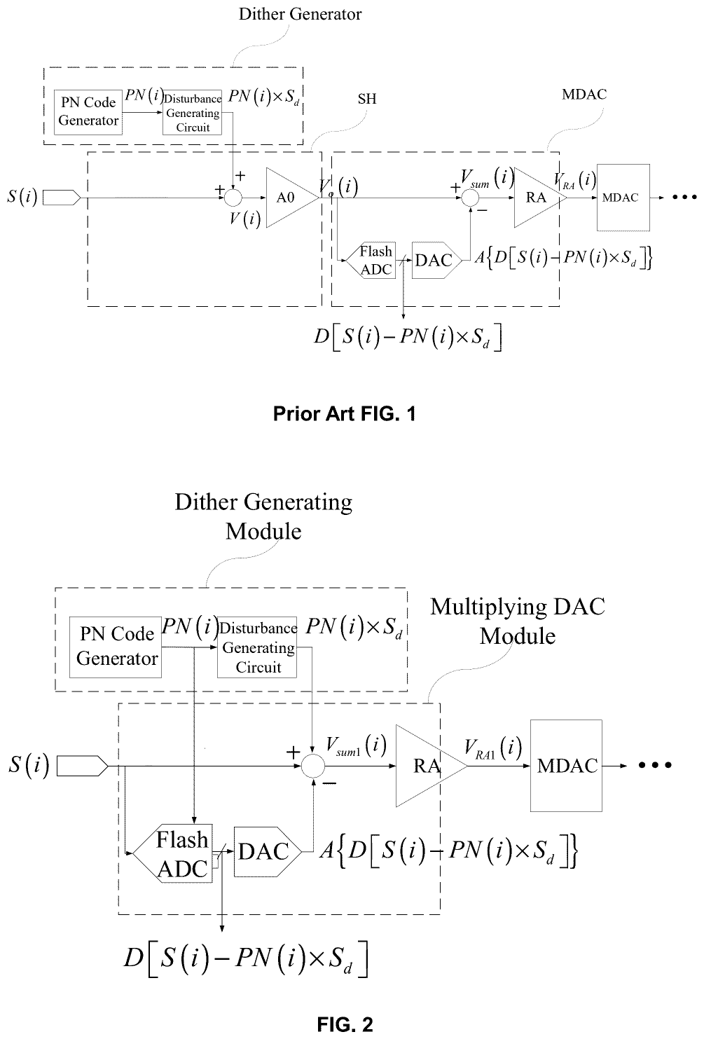

Please refer to FIGS. 1 to 8. It should be noted that the diagrams provided in one or more embodiments only illustrate the basic concept of the present application in a schematic manner, so the diagrams only show the components related to the present application rather than being drawn according to the number, shape, and size of the components in actual implementation. The type, quantity, and scale of each component in actual implementation can be changed at will, and the component layout type may also be more complicated. The structure, scale, size, etc. shown in the drawings attached to this specification are only used to match the content disclosed in the specification for people familiar with this technology to understand and read, and are not used to limit the limiting conditions that the present application can be implemented, so they have no technical substantive significance. Any modification of the structure, change of the proportional relationship, or adjustment of the size should still fall within the scope of the technical content disclosed by the present application without affecting the effect that the present application can produce and the purpose that the present application can achieve.

As described above in the background section, the inventors have found that a conventional pipeline analog-to-digital converter with input dither shown in FIG. 1 includes a dither generator, a sample-and-hold circuit (SH), and a multi-stage cascaded multiplying digital-to-analog converter (MDAC).

The dither generator includes two parts: a PN code generator and a disturbance generating circuit, wherein the PN code generator generates a dither number PN(i), and the disturbance generating circuit generates a dither PN(i)×S_{d}.

The sample-and-hold circuit (SH) samples the input signal S(i) and the dither PN(i)×S_{d} at the same time, and sums these two signals to output V(i). Then the high-performance amplifier A₀ amplifies V(i). Generally, the gain of the high-performance amplifier A₀ is G₀=1, and the output of the high-performance amplifier is Vₒ(i).

$$V ( i ) = S ( i ) = PN ( i ) \times {S}_{d} \qquad ( 1 )$$

$${V}_{o} ( i ) = {G}_{0} \times ( S ( i ) + PN ( i ) \times {S}_{d} ) = S ( i ) + PN ( i ) \times {S}_{d} \qquad ( 2 )$$

The multiplying digital-to-analog converter (MDAC) includes a Flash ADC, an analog-to-digital converter (DAC), and a residual amplifier (RA). The Flash ADC converts the input into a digital signal D[S(i)+PN(i)×S_{d}], and the DAC converts it into an analog signal A{D[S(i)+PN(i)×S_{d}]}. The gain of the RA is G₁, the input of the RA is Vₛᵤₘ(i), and the output of the RA is V_{RA}(i).

$${V}_{sum} ( i ) = [ S ( i ) + PN ( i ) \times {S}_{d} ] - A \{ D [ S ( i ) + PN ( i ) \times {S}_{d} ] \} \qquad ( 3 )$$

$${V}_{RA} ( i ) = {G}_{1} \{ [ S ( i ) + PN ( i ) \times {S}_{d} ] - A \{ D [ S ( i ) + PN ( i ) \times {S}_{d} ] \} \} \qquad ( 4 )$$

However, for pipeline analog-to-digital converters with input dithers, since the performance of the sample-and-hold circuit is required to be greater than or equal to the performance of the analog-to-digital converter, it faces huge challenges in terms of power consumption, area, and design difficulty. In particular, the high-performance amplifier in the sample-and-hold circuit often consumes ¼ of the power consumption and ⅛ of the area of the entire analog-to-digital converter.

Therefore, there is a need for a dither pre-quantization technology solution that can inject dithers into the input signal without going through a sample-and-hold circuit, so as to reduce the overall power consumption, area, and design difficulty of the analog-to-digital converter.

Based on this, the present application proposes a dither pre-quantization technical solution for a pipeline analog-to-digital converter. Instead of using a sample-and-hold circuit, dithers are equivalently injected into the input signal inside the multiplying digital-to-analog conversion module to reduce the overall power consumption, area, and design difficulty of the analog-to-digital converter.

The present application provides a pipeline analog-to-digital converter architecture with dither pre-quantization technology, which pre-quantizes the disturbance and equivalently adds the dither to the input signal, thereby achieving the purpose of equivalently injecting the dither into the input signal, thereby reducing the overall power consumption, area, and design difficulty of the analog-to-digital converter.

In one or more embodiments, the present application proposes a pipeline analog-to-digital converter, which includes N pipeline conversion stages cascaded in sequence. In the first N−1 pipeline conversion stages, as shown in FIG. 2, at least one pipeline conversion stage includes: a dither generating module generating a random digital signal PN(i) and performing digital-to-analog conversion on the random digital signal PN(i) to obtain a random analog signal PN(i)×S_{d}; and a multiplying digital-to-analog conversion module including a flash-type analog-to-digital conversion unit (Flash ADC), a digital-to-analog conversion unit (DAC) and an operation unit, wherein the flash-type analog-to-digital conversion unit receives a first analog signal S(i) and performs analog-to-digital conversion on the first analog signal S(i) to obtain a digital signal D[S(i)+PN(i)×S_{d}], the digital-to-analog conversion unit receives the digital signal D[S(i)+PN(i)×S_{d}] and performs digital-to-analog conversion on the digital signal D[S(i)+PN(i)×S_{d}] to obtain a second analog signal A{D[S(i)+PN(i)×S_{d}]}, the operation unit receives the first analog signal S(i), the second analog signal A{D[S(i)+PN(i)×S_{d}]}, and the random analog signal PN(i)×S_{d}, and the operation unit adds the random analog signal PN(i)×S_{d} to the first analog signal S(i) and subtracts the second analog signal A{D[S (i)+PN(i)×S_{d}]} to obtain a residual analog signal Vₛᵤₘ₁(i); wherein the flash-type analog-to-digital conversion unit also receives the random digital signal PN(i); under the action of the random digital signal PN(i), a quantization reference level of a comparator in the flash-type analog-to-digital conversion unit is shifted to equivalently add a dither signal to the first analog signal S(i); N is an integer greater than 2.

In one or more embodiments, as shown in FIG. 2, the dither generating module includes: a PN code generator generating the random digital signal PN(i); and a disturbance generating circuit performing digital-to-analog conversion on the random digital signal PN(i) to obtain the random analog signal PN(i)×S_{d}.

In one or more embodiments, as shown in FIG. 2, the flash-type analog-to-digital conversion unit includes a quantization reference level generating circuit, which generates a plurality of quantization reference levels of different values. The quantization reference level generating circuit is connected to the random digital signal PN(i), and shifts each quantization reference level under the action of the random digital signal PN(i).

In one or more embodiments, compared with the structure shown in FIG. 1, the pipeline analog-to-digital converter shown in FIG. 2 removes the sample-and-hold circuit (SH), and directly inputs the output PN(i) of the PN code generator into the flash-type analog-to-digital conversion unit. In order to realize the prequantization function, the present application shows a flash-type analog-to-digital conversion unit with prequantization. The input of the flash-type analog-to-digital conversion unit with prequantization is S(i) and PN(i), and the output is D[S(i)+PN(i)×S_{d}], thereby achieving the purpose of prequantization while generating the dither PN(i)×S_{d}.

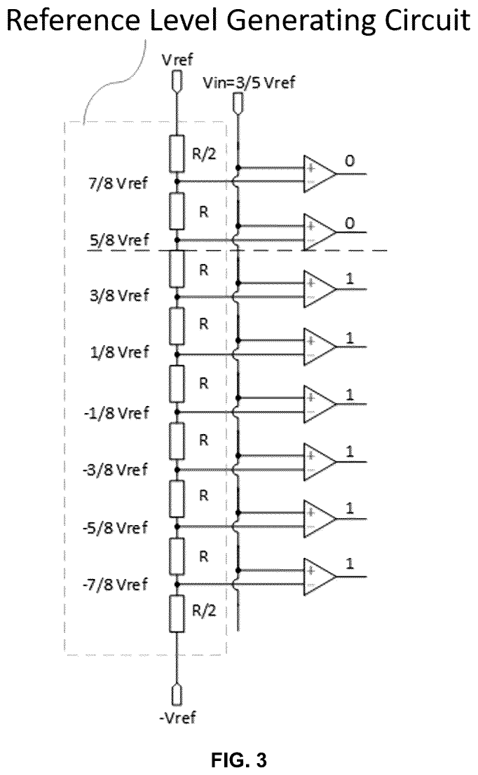

According to FIG. 3 to FIG. 5, the principle of the flash-type analog-to-digital conversion unit with pre-quantization function is further introduced.

FIG. 3 shows the principle of the comparator of the flash-type analog-to-digital conversion unit. The comparator compares the input signal Vin with the designed quantization reference levels (±⅞Vref, ±⅝Vref, ±⅜Vref, ±⅛Vref) to obtain the quantization result, where ±Vref is the reference voltage of the flash-type analog-to-digital conversion unit, and the entire quantization range is from −Vref to +Vref.

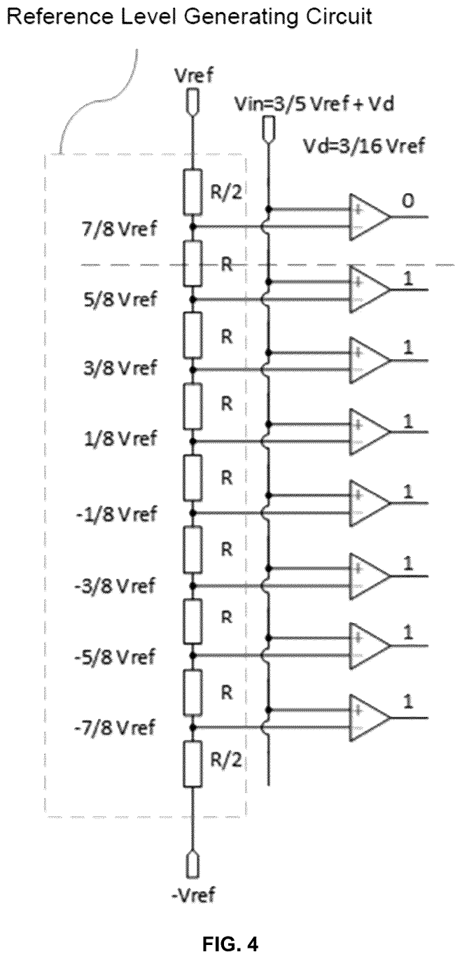

FIG. 4 shows the situation where the flash-type analog-to-digital conversion unit quantizes Vin+Vd after the input signal Vin is added to the signal Vd.

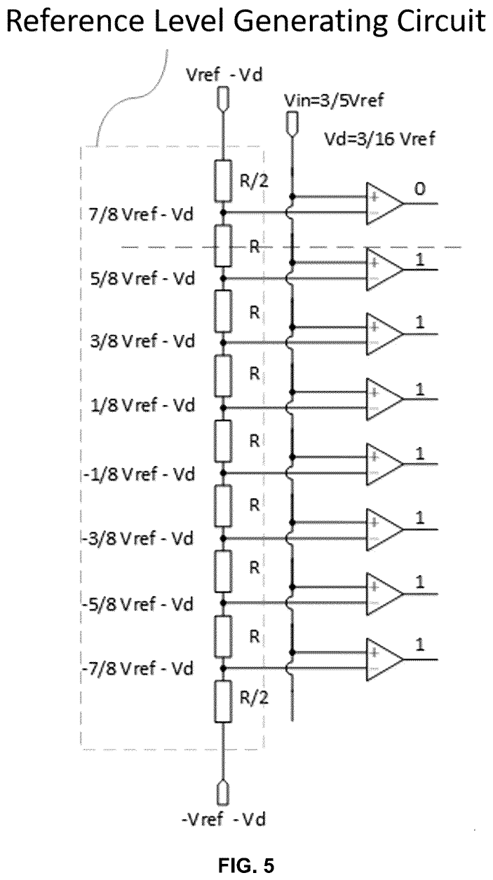

FIG. 5 shows the situation where the flash-type analog-to-digital conversion unit quantizes the input signal Vin after each quantization reference level is shifted downward by Vd (±⅞Vref−Vd, ±⅝Vref−Vd, ±⅜Vref−Vd, ±⅛Vref−Vd) with the input signal Vin remaining unchanged, and the result obtained by the flash-type analog-to-digital conversion unit is consistent with the result of quantizing Vin+Vd in FIG. 4. Therefore, when the quantization reference level changes by an offset Vd, the output result of the flash-type analog-to-digital conversion unit is consistent with the output result after an additional level Vd is injected into the input signal Vin of the flash-type analog-to-digital conversion unit, that is, for the flash-type analog-to-digital conversion unit, the two are equivalent.

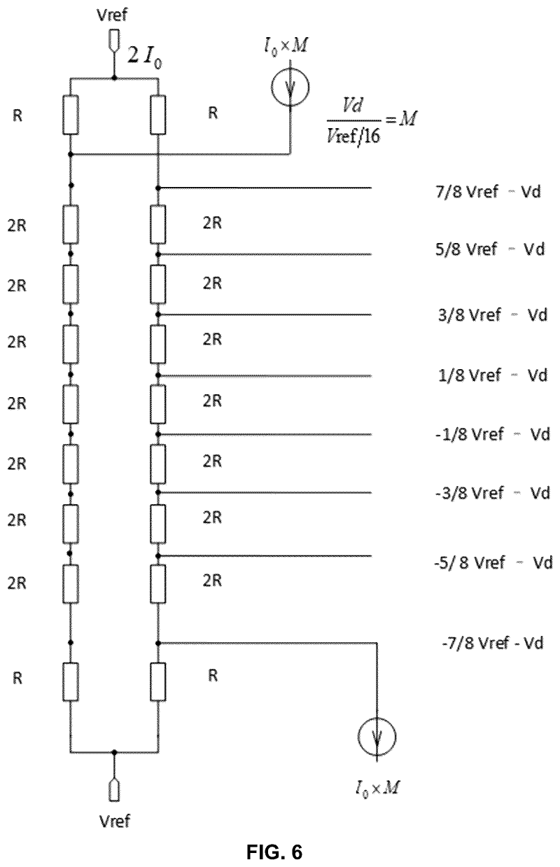

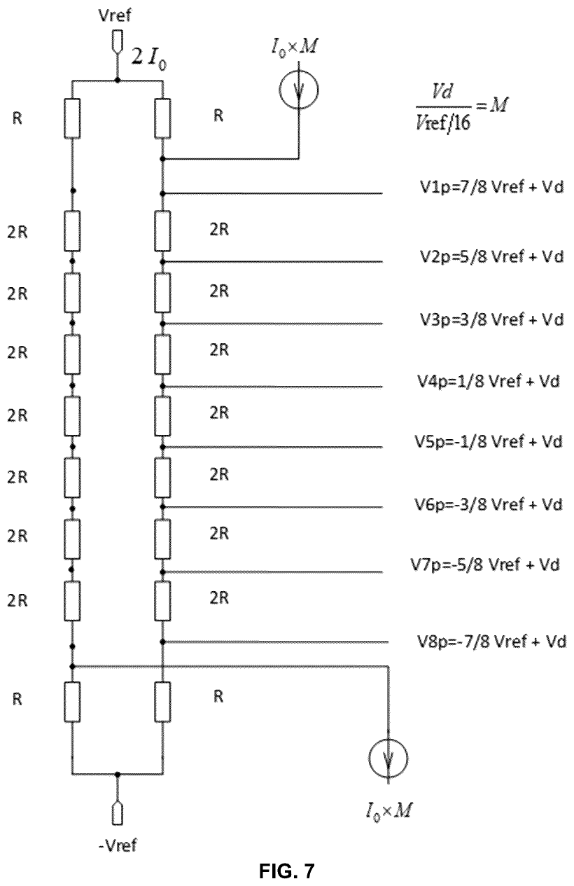

Therefore, as shown in FIG. 6 and FIG. 7, the present application provides a novel quantization reference level generating circuit, and as long as the relationship M between Vd and 1/16Vref is known, the quantization reference level can be changed by adjusting the current. FIG. 6 shows the case where the reference level is shifted down, and FIG. 7 shows the case where the reference level is shifted up.

$$M = \frac{Vd}{Vref / 16} \qquad ( 5 )$$

In one or more embodiments, by using the novel quantization reference level generating circuit provided by the present application, let V_{d}=S_{d}, and V_{d} is generally a fixed value. Therefore, to realize the pipeline architecture with the function of pre-quantizing the injected dither PN(i)×S_{d} shown in FIG. 2, it is only necessary to transmit PN(i) to the flash-type analog-to-digital conversion unit and select whether to move the reference level up or down (when PN(i) is 1, the reference level moves down; when PN(i) is −1, the reference level moves up) according to the value of PN(i).

At this time, the output of the flash-type analog-to-digital conversion unit is D[S(i)+PN(i)×S_{d}], the output of the digital-to-analog conversion unit is A{D[S(i)+PN(i)×S_{d}]}, the input of the residual amplifier is Vₛᵤₘ₁(i), and the output of the residual amplifier is V_{RA1}(i).

$${V}_{sum 1} ( i ) = [ S ( i ) + PN ( i ) \times {S}_{d} ] - A \{ D [ S ( i ) + PN ( i ) \times {S}_{d} ] \} \qquad ( 6 )$$

$${V}_{RA 1} ( i ) = {G}_{1} \{ [ S ( i ) + PN ( i ) \times {S}_{d} ] - A \{ D [ S ( i ) + PN ( i ) \times {S}_{d} ] \} \} \qquad ( 7 )$$

It can be seen that the expressions of formulas (3) and (6) are the same, and the expressions of formulas (4) and (7) are the same. Therefore, after removing the sample-and-hold circuit, the pipeline analog-to-digital converter with dither prequantization technology disclosed by the present application equivalently adds dithers to the input signal, and the function of the entire design is not affected in any way.

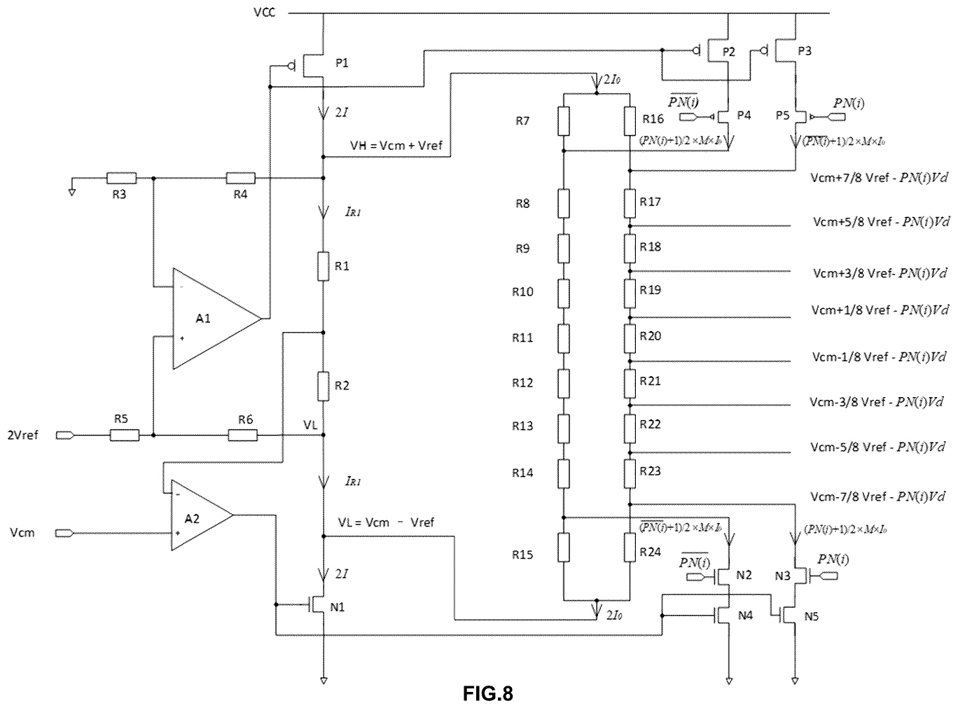

In one or more embodiments, in an optional embodiment of the present application, a quantization reference level generating circuit is provided, as shown in FIG. 8, the quantization reference level generating circuit includes: a current and voltage generating subcircuit generating a first voltage VH and a second voltage VL, and generating a reference current 2I; a voltage dividing subcircuit connected to the first voltage VH and the second voltage VL, where the voltage dividing subcircuit combines the first voltage VH and the second voltage VL to perform voltage dividing processing to obtain a plurality of quantization reference levels of different values; and a current mirror selecting subcircuit connected to the current and voltage generation subcircuit and the voltage dividing subcircuit to performs mirror copying on the reference current 2I to obtain the mirror current and connected to the random digital signal PN(i) to selectively input the mirror current is into the voltage dividing subcircuit under the control of the random digital signal PN(i) such that each quantization reference level is shifted by a voltage difference correspondingly generated by the mirror current.

In one or more embodiments, as shown in FIG. 8, the current and voltage generating subcircuit includes a first operational amplifier A1, a second operational amplifier A2, a first PMOS transistor P1, a first NMOS transistor N1, a first resistor R1, a second resistor R2, a third resistor R3, a fourth resistor R4, a fifth resistor R5, and a sixth resistor R6. The source of the first PMOS transistor P1 is connected to the power supply voltage VCC, the drain of the first PMOS transistor P1 is connected to the drain of the first NMOS transistor N1 via the first resistor R1 and the second resistor R2 connected in series in sequence, the source of the first NMOS transistor is grounded, the inverting input end of the first operational amplifier A1 is grounded via the third resistor R3 connected in series, the inverting input end of the first operational amplifier A1 is also connected to the drain of the first PMOS transistor P1 via the fourth resistor R4 connected in series, the non-inverting input end of the first operational amplifier A1 is connected to the first reference voltage 2Vref via the fifth resistor R5 connected in series, the non-inverting input end of the first operational amplifier A1 is connected to the drain of the first NMOS transistor N1 via the sixth resistor R6 connected in series, the output end of the first operational amplifier A1 is connected to the gate of the first PMOS transistor P1, the inverting input end of the second operational amplifier A2 is connected to the common end of the first resistor R1 and the second resistor R2, the non-inverting input end of the second operational amplifier A2 is connected to the second reference voltage Vcm, and the output end of the second operational amplifier A2 is connected to the gate of the first NMOS transistor N1; the drain of the first PMOS transistor P1 outputs the first voltage VH, the drain of the first NMOS transistor N1 outputs the second voltage VL, the drain of the first PMOS transistor P1 outputs the reference current 2I, and the reference current 2I is input to the drain of the first NMOS transistor N1.

In one or more embodiments, the resistance value of the first resistor R1 is equal to the resistance value of the second resistor R2, the resistance value of the third resistor R3, the resistance value of the fourth resistor R4, the resistance value of the fifth resistor R5, and the resistance value of the sixth resistor R6 are equal, and the resistance value of the first resistor R1 is greater than and much greater than the resistance value of the third resistor R3. For example, the resistance value of the third resistor R3 is in the ohm level, and the resistance value of the first resistor R1 is in the megohm level.

In one or more embodiments, as shown in FIG. 8, the input current of the first operational amplifier A1 is ignored, 2I₀=2I−I_{R1}, since the resistance of the first resistor R1 and the resistance of the second resistor R2 are large, the magnitude of the current I_{R1} flowing through the first resistor R1 and the second resistor R2 can be ignored, that is, I_{R1}≈0, therefore, 2I₀=2I.

At the same time, as shown in FIG. 8, due to the setting of the connection relationship and the resistance relationship, it can be deduced that the first voltage VH=Vcm+Vref and the second voltage VL=Vcm−Vref.

In one or more embodiments, as shown in FIG. 8, the voltage dividing subcircuit includes a seventh resistor R7, an eighth resistor R8, a ninth resistor R9, a tenth resistor R10, an eleventh resistor R11, a twelfth resistor R12, a thirteenth resistor R13, a fourteenth resistor R14, a fifteenth resistor R15, a sixteenth resistor R16, a seventeenth resistor R17, an eighteenth resistor R18, a nineteenth resistor R19, a twentieth resistor R20, a twenty-first resistor R21, a twenty-second resistor R22, a twenty-third resistor R23, and a twenty-fourth resistor R24. One end of the seventh resistor R7 is connected to the drain of the first PMOS transistor P1, the other end of the seventh resistor R7 is connected to the drain of the first NMOS transistor N1 through the eighth resistor R8, the ninth resistor R9, the tenth resistor R10, the eleventh resistor R11, the twelfth resistor R12, the thirteenth resistor R13, the fourteenth resistor R14, and the fifteenth resistor R15 which are connected in series in sequence, one end of the sixteenth resistor R16 is connected to the drain of the first PMOS transistor P1, the other end of the sixteenth resistor R16 is connected to the drain of the first NMOS transistor N1 through the seventeenth resistor R17, the eighteenth resistor R18, the nineteenth resistor R19, the twentieth resistor R20, the twenty-first resistor R21, the twenty-second resistor R22, the twenty-third resistor R23 and the twenty-fourth resistor R24 which are connected in series in sequence. The common end of the sixteenth resistor R16 and the seventeenth resistor R17 outputs a quantization reference level, the common end of the seventeenth resistor R17 and the eighteenth resistor R18 outputs a quantization reference level, the common end of the eighteenth resistor R18 and the nineteenth resistor R19 outputs a quantization reference level, the common end of the nineteenth resistor R19 and the twentieth resistor R20 outputs a quantization reference level, the common end of the twentieth resistor R20 and the twenty-first resistor R21 outputs a quantization reference level, the common end of the twenty-first resistor R21 and the twenty-second resistor R22 outputs a quantization reference level, the common end of the twenty-second resistor R22 and the twenty-third resistor R23 outputs a quantization reference level, and the common end of the twenty-third resistor R23 and the twenty-fourth resistor R24 outputs a quantization reference level.

In one or more embodiments, the voltage dividing subcircuit includes two voltage dividing branches. The resistance value of the seventh resistor R7, the resistance value of the fifteenth resistor R15, the resistance value of the sixteenth resistor R16, and the resistance value of the twenty-fourth resistor R24 are equal, the resistance value of the eighth resistor R8, the resistance value of the ninth resistor R9, the resistance value of the tenth resistor R10, the resistance value of the eleventh resistor R11, the resistance value of the twelfth resistor R12, the resistance value of the thirteenth resistor R13, the resistance value of the fourteenth resistor R14, the resistance value of the seventeenth resistor R17, the resistance value of the eighteenth resistor R18, the resistance value of the nineteenth resistor R19, the resistance value of the twentieth resistor R20, the resistance value of the twenty-first resistor R21, the resistance value of the twenty-second resistor R22 and the resistance value of the twenty-third resistor R23 are equal; the ratio of the resistance value of the eighth resistor R8 to the resistance value of the seventh resistor R7 is 2:1.

In one or more embodiments, as shown in FIG. 8, the voltage dividing subcircuit combines the first voltage VH and the second voltage VL to perform voltage division processing to obtain quantization reference levels Vcm±⅞Vref, Vcm±⅝Vref, Vcm±⅜Vref, and Vcm±⅛Vref.

In one or more embodiments, as shown in FIG. 8, the random digital signal includes a first random digital signal P̅N̅(̅i̅)̅ and a second random digital signal PN(i). The current mirror selecting subcircuit includes a second PMOS transistor P2, a third PMOS transistor P3, a fourth PMOS transistor P4, a fifth PMOS transistor P5, a second NMOS transistor N2, a third NMOS transistor N3, a fourth NMOS transistor N4, and a fifth NMOS transistor N5. The source of the second PMOS transistor P2 is connected to the power supply voltage VCC, the gate of the second PMOS transistor P2 is connected to the gate of the first PMOS transistor P1, the drain of the second PMOS transistor P2 is connected to the source of the fourth PMOS transistor P4, the gate of the fourth PMOS transistor P4 is connected to the first random digital signal P̅N̅(̅i̅)̅, the drain of the fourth PMOS transistor P4 is connected to the common end of the seventh resistor R7 and the eighth resistor R8, the source of the third PMOS transistor P3 is connected to the power supply voltage VCC, the gate of the third PMOS transistor P3 is connected to the gate of the first PMOS transistor P1, the drain of the third PMOS transistor P3 is connected to the source of the fifth PMOS transistor P5, the gate of the fifth PMOS transistor P5 is connected to the second random digital signal PN(i), the drain of the fifth PMOS transistor P5 is connected to the common end of the sixteenth resistor R16 and the seventeenth resistor R17, the drain of the second NMOS transistor N2 is connected to the common end of the fourteenth resistor R14 and the fifteenth resistor R15, the gate of the second NMOS transistor N2 is connected to the first random digital signal P̅N̅(̅i̅)̅, the source of the second NMOS transistor N2 is connected to the drain of the fourth NMOS transistor N4, the gate of the fourth NMOS transistor N4 is connected to the gate of the first NMOS transistor N1, the source of the fourth NMOS transistor N4 is grounded, the drain of the third NMOS transistor N3 is connected to the common end of the twenty-third resistor R23 and the twenty-fourth resistor 24, the gate of the third NMOS transistor N3 is connected to the second random digital signal PN(i), the source of the third NMOS transistor N3 is connected to the drain of the fifth NMOS transistor N5, the gate of the fifth NMOS transistor N5 is connected to the gate of the first NMOS transistor N1, and the source of the fifth NMOS transistor N5 is grounded.

In one or more embodiments, the ratio of the width-to-length ratio of the second PMOS transistor P2 to the width-to-length ratio of the first PMOS transistor P1 is M:2, and the ratio of the width-to-length ratio of the third PMOS transistor P3 to the width-to-length ratio of the first PMOS transistor P1 is M:2; the ratio of the width-to-length ratio of the second NMOS transistor N2 to the width-to-length ratio of the first NMOS transistor N1 is M:2, and the ratio of the width-to-length ratio of the third NMOS transistor N3 to the width-to-length ratio of the first NMOS transistor N1 is M:2; the first random digital signal P̅N̅(̅i̅)̅ and the second random digital signal PN(i) are inverted signals to each other; when the value of the first random digital signal P̅N̅(̅i̅)̅ is 1, the value of the second random digital signal PN(i) is −1; when the value of the first random digital signal P̅N̅(̅i̅)̅ is −1, the value of the second random digital signal PN(i) is 1.

In one or more embodiments, as shown in FIG. 8, based on the connection relationship of the current mirror selecting subcircuit and the setting relationship of the transistor characteristic size, the drain input current of the third NMOS transistor N3 and the drain output current of the fourth PMOS transistor P4 are both (P̅N̅(̅i̅)̅+1)/2×M×I₀, and the drain input current of the second NMOS transistor N2 and the drain output current of the fifth PMOS transistor P5 are both (PN(i)+1)/2×M×I₀.

In one or more embodiments, as shown in FIG. 8, when the second random digital signal PN(i) is 1, and the first random digital signal P̅N̅(̅i̅)̅ is −1, the third NMOS transistor N3 and the fourth PMOS transistor P4 are turned on, the second NMOS transistor N2 and the fifth PMOS transistor P5 are turned off, and the mirror current M×I₀ flows into the first voltage dividing branch, so that the quantization reference levels move down to Vcm±⅞Vref−Vd, Vcm±⅝Vref−Vd, Vcm±⅜Vref−Vd, and Vcm±⅛Vref−Vd; when the second random digital signal PN(i) is −1, and the first random digital signal P̅N̅(̅i̅)̅ is 1, the third NMOS transistor N3 and the fourth PMOS transistor P4 are turned off, the second NMOS transistor N2 and the fifth PMOS transistor P5 are turned on, and the mirror current M×I₀ flows into the second voltage dividing branch, so that the quantization reference levels move up to Vcm±⅞Vref+Vd, Vcm±⅝Vref+Vd, Vcm±⅜Vref+Vd, and Vcm±⅛Vref+Vd.

To sum up, in the pipeline analog-to-digital converter provided by the present application, at least one pipeline conversion stage includes a dither generating module and a multiplying digital-to-analog conversion module. The flash-type analog-to-digital conversion unit in the multiplying digital-to-analog conversion module includes a quantization reference level generating circuit. Under the action of a random digital signal, the quantization reference level of the comparator in the flash-type analog-to-digital conversion unit is shifted by the quantization reference level generating circuit, such that the dither signal is equivalently added to the input analog signal. An additional sample-and-hold circuit is no longer required, and the equivalent injection of dither can be achieved inside the multiplying digital-to-analog conversion module, thereby reducing the design difficulty and power consumption of the pipeline analog-to-digital converter, and reducing the area of the pipeline analog-to-digital converter, thereby reducing the production cost.

The pipeline analog-to-digital converter provided by the present application has at least the following beneficial effects.

At least one pipeline conversion stage includes a dither generating module and a multiplying digital-to-analog conversion module. The flash-type analog-to-digital conversion unit in the multiplying digital-to-analog conversion module receives a random digital signal. Under the action of the random digital signal, the quantization reference level of the comparator in the flash-type analog-to-digital conversion unit is shifted to equivalently add the dither signal to the first analog signal. No additional sample-and-hold circuit is required, and the equivalent injection of dither can be achieved inside the multiplying digital-to-analog conversion module, which reduces the design difficulty and power consumption of the pipeline analog-to-digital converter, and reduces the area of the pipeline analog-to-digital converter, thereby reducing the production cost.

The above embodiments are merely illustrative of the principles and effects of the present application, and are not intended to limit the present application. Anyone familiar with the art may modify or alter the above embodiments without departing from the spirit and scope of the present application. Therefore, all equivalent modifications or alterations made by a person of ordinary skill in the art without departing from the spirit and technical concept disclosed by the present application shall still be covered by the claims of the present application.

What is claimed is:

1. A pipeline analog-to-digital converter, wherein the pipeline analog-to-digital converter comprises N pipeline conversion stages cascaded in sequence, and at least one of first N−1 pipeline conversion stages includes:
a dither generating module configured to generate a random digital signal and perform digital-to-analog conversion on the random digital signal to obtain a random analog signal; and
a multiplying digital-to-analog conversion module, including a flash-type analog-to-digital conversion unit, a digital-to-analog conversion unit, and an operation unit, wherein the flash-type analog-to-digital conversion unit is configured to receive a first analog signal and perform analog-to-digital conversion on the first analog signal to obtain a digital signal, the digital-to-analog conversion unit is configured to receive the digital signal and perform digital-to-analog conversion on the digital signal to obtain a second analog signal, the operation unit is configured to receive the first analog signal, the second analog signal, and the random analog signal, and is configured to obtain a residual analog signal equal to the first analog signal plus the random analog signal minus the second analog signal,
wherein the flash-type analog-to-digital conversion unit is also configured to receive the random digital signal, and shift a quantization reference level of a comparator in the flash-type analog-to-digital conversion unit under an action of the random digital signal, to equivalently add a dither signal to the first analog signal; N is an integer greater than 2.

2. The pipeline analog-to-digital converter according to claim 1, wherein the flash-type analog-to-digital conversion unit includes a quantization reference level generating circuit, the quantization reference level generating circuit is configured to generate a plurality of quantization reference levels of different values, and the quantization reference level generating circuit is connected to the random digital signal to shift each of the quantization reference levels under the action of the random digital signal.

3. The pipeline analog-to-digital converter according to claim 2, wherein the quantization reference level generating circuit includes:
a current and voltage generating subcircuit configured to generate a first voltage and a second voltage, and generate a reference current;
a voltage dividing subcircuit connected to the first voltage and the second voltage, and configured to combine the first voltage and the second voltage to perform voltage dividing processing to obtain the plurality of the quantization reference levels of different values; and
a current mirror selecting subcircuit connected to the current and voltage generating subcircuit and the voltage dividing subcircuit to mirroring the reference current to obtain a mirror current, and also connected to the random digital signal to selectively input the mirror current into the voltage dividing subcircuit under a control of the random digital signal, to shift each of the quantization reference levels by a voltage difference respectively generated by the mirror current.

4. The pipeline analog-to-digital converter according to claim 3, wherein the current and voltage generating subcircuit includes a first operational amplifier, a second operational amplifier, a first PMOS transistor, a first NMOS transistor, a first resistor, a second resistor, a third resistor, a fourth resistor, a fifth resistor, and a sixth resistor, a source of the first PMOS transistor is connected to a power supply voltage, a drain of the first PMOS transistor is connected to a drain of the first NMOS transistor via the first resistor and the second resistor connected in series in sequence, a source of the first NMOS transistor is grounded, an inverting input end of the first operational amplifier is grounded via the third resistor connected in series, the inverting input end of the first operational amplifier is also connected to the drain of the first PMOS transistor via the fourth resistor connected in series, a non-inverting input end of the first operational amplifier is connected to a first reference voltage via the fifth resistor connected in series, the non-inverting input end of the first operational amplifier is also connected to the drain of the first NMOS transistor via the sixth resistor connected in series, an output end of the first operational amplifier is connected to a gate of the first PMOS transistor, an inverting input end of the second operational amplifier is connected to a common end of the first resistor and the second resistor, a non-inverting input end of the second operational amplifier is connected to a second reference voltage, and an output end of the second operational amplifier is connected to a gate of the first NMOS transistor; wherein the drain of the first PMOS transistor outputs the first voltage, the drain of the first NMOS transistor outputs the second voltage, the drain of the first PMOS transistor outputs the reference current, and the drain of the first NMOS transistor inputs the reference current.

5. The pipeline analog-to-digital converter according to claim 4, wherein a resistance value of the first resistor is equal to a resistance value of the second resistor, resistance values of the third resistor, the fourth resistor, the fifth resistor, and the sixth resistor are equal, and the resistance value of the first resistor is greater than the resistance value of the third resistor.

6. The pipeline analog-to-digital converter according to claim 4, wherein the voltage dividing subcircuit includes a seventh resistor, an eighth resistor, a ninth resistor, a tenth resistor, an eleventh resistor, a twelfth resistor, a thirteenth resistor, a fourteenth resistor, a fifteenth resistor, a sixteenth resistor, a seventeenth resistor, an eighteenth resistor, a nineteenth resistor, a twentieth resistor, a twenty-first resistor, a twenty-second resistor, a twenty-third resistor, and a twenty-fourth resistor; a first end of the seventh resistor is connected to the drain of the first PMOS transistor, a second end of the seventh resistor is connected to the drain of the first NMOS transistor via the eighth resistor, the ninth resistor, the tenth resistor, the eleventh resistor, the twelfth resistor, the thirteenth resistor, the fourteenth resistor, and the fifteenth resistor connected in series in sequence; a first end of the sixteenth resistor is connected to the drain of the first PMOS transistor, a second end of the sixteenth resistor is connected to the drain of the first PMOS transistor via the seventeenth resistor, the eighteenth resistor, the nineteenth resistor, the twentieth resistor, the twenty-first resistor, the twenty-second resistor, the twenty-third resistor, and the twenty-fourth resistor connected in series in sequence; wherein, a common end of the sixteenth resistor and the seventeenth resistor outputs one of the quantization reference levels, a common end of the seventeenth resistor and the eighteenth resistor outputs one of the quantization reference levels, a common end of the eighteenth resistor and the nineteenth resistor outputs one of the quantization reference levels, a common end of the nineteenth resistor and the twentieth resistor outputs one of the quantization reference levels, a common end of the twentieth resistor and the twenty-first resistor outputs one of the quantization reference levels, a common end of the twenty-first resistor and the twenty-second resistor outputs one of the quantization reference levels, a common end of the twenty-second resistor and the twenty-third resistor outputs one of the quantization reference levels, and a common end of the twenty-third resistor and the twenty-fourth resistor outputs one of the quantization reference levels.

7. The pipeline analog-to-digital converter according to claim 6, wherein resistance values of the seventh resistor, the fifteenth resistor, the sixteenth resistor, and the twenty-fourth resistor are equal, resistance values of the eighth resistor, the ninth resistor, the tenth resistor, the eleventh resistor, the twelfth resistor, the thirteenth resistor, the fourteenth resistor, the seventeenth resistor, the eighteenth resistor, the nineteenth resistor, the twenty-tenth resistor, the twenty-first resistor, the twenty-second resistor, and the twenty-third resistor are equal; and a ratio of the resistance value of the eighth resistor to the resistance value of the seventh resistor is 2:1.

8. The pipeline analog-to-digital converter according to claim 6, wherein the random digital signal includes a first random digital signal and a second random digital signal, the current mirror selecting subcircuit includes a second PMOS transistor, a third PMOS transistor, a fourth PMOS transistor, a fifth PMOS transistor, a second NMOS transistor, a third NMOS transistor, a fourth NMOS transistor, and a fifth NMOS transistor, a source of the second PMOS transistor is connected to the power supply voltage, a gate of the second PMOS transistor is connected to the gate of the first PMOS transistor, a drain of the second PMOS transistor is connected to a source of the fourth PMOS transistor, a gate of the fourth PMOS transistor is connected to the first random digital signal, a drain of the fourth PMOS transistor is connected to a common end of the seventh resistor and the eighth resistor, a source of the third PMOS transistor is connected to the power supply voltage, a gate of the third PMOS transistor is connected to the gate of the first PMOS transistor, a drain of the third PMOS transistor is connected to a source of the fifth PMOS transistor, a gate of the fifth PMOS transistor is connected to the second random digital signal, a drain of the fifth PMOS transistor is connected to the common end of the sixteenth resistor and the seventeenth resistor, a drain of the second NMOS transistor is connected to a common end of the fourteenth resistor and the fifteenth resistor, a gate of the second NMOS transistor is connected to the first random digital signal, a source of the second NMOS transistor is connected to a drain of the fourth NMOS transistor, a gate of the fourth NMOS transistor is connected to the gate of the first NMOS transistor, a source of the fourth NMOS transistor is grounded, a drain of the third NMOS transistor is connected to the common end of the twenty-third resistor and the twenty-fourth resistor, a gate of the third NMOS transistor is connected to the second random digital signal, a source of the third NMOS transistor is connected to a drain of the fifth NMOS transistor, a gate of the fifth NMOS transistor is connected to the gate of the first NMOS transistor, and a source of the fifth NMOS transistor is grounded.

9. The pipeline analog-to-digital converter according to claim 8, wherein a ratio of a width-to-length ratio of the second PMOS transistor to a width-to-length ratio of the first PMOS transistor is M:2, and a ratio of a width-to-length ratio of the third PMOS transistor to a width-to-length ratio of the first PMOS transistor is M:2; a ratio of a width-to-length ratio of the second NMOS transistor to a width-to-length ratio of the first NMOS transistor is M:2, and a ratio of a width-to-length ratio of the third NMOS transistor to a width-to-length ratio of the first NMOS transistor is M:2.

10. The pipeline analog-to-digital converter according to claim 8, wherein the first random digital signal and the second random digital signal are mutually inverted signals; when a value of the first random digital signal is 1, a value of the second random digital signal is −1; when a value of the first random digital signal is −1, a value of the second random digital signal is 1.
